(19) United States
(12) Patent Application Publication
(10) Pub. No.: US 2015/0228594 A1
(43) Pub. Date: Aug. 13, 2015

(54) VIA UNDER THE INTERCONNECT STRUCTURES FOR SEMICONDUCTOR DEVICES

(71) Applicant: QUALCOMM INCORPORATED, San Diego, CA (US)

(72) Inventors: Reynante Tamunan Alvarado, San Diego, CA (US); Ruey Kae Zang, San Diego, CA (US); Lizabeth Ann Keser, San Diego, CA (US)

(73) Assignee: QUALCOMM INCORPORATED, San Diego, CA (US)

(21) Appl. No.: 14/221,582

(22) Filed: Mar. 21, 2014

Related U.S. Application Data
(60) Provisional application No. 61/939,596, filed on Feb. 13, 2014.

(51) Int. Cl. H01L 23/00; H01L 23/48

(52) U.S. Cl. CPC H01L 24/06; H01L 23/481; H01L 24/94; H01L 24/03; H01L 2224/0239; H01L 2224/0601; H01L 2224/02372; H01L 2224/94

(57) ABSTRACT

A semiconductor device is provided that has a redistribution layer with reduced resistance. The semiconductor device comprises a plurality of bonding pads on a substrate, a redistribution layer coupled to the bonding pads through a plurality of vias, a dielectric layer over the redistribution layer, that includes an opening that exposes a portion of the redistribution layer. The bonding pads are at least partially under the opening.

### CROSS-REFERENCE TO RELATED APPLICATION

Pursuant to 35 U.S.C. §119(e), this application claims priority to the filing date of U.S. Provisional Patent Application No. 61/939,596, filed. Feb. 13, 2014, which is incorporated by reference in its entirety.

### TECHNICAL FIELD

This application relates to semiconductor devices, and more particularly, to semiconductor devices including via under the interconnect structures.

### BACKGROUND

Modern integrated circuit (IC) applications typically have high input/output (I/O) pinout requirements. However, high pinouts pose problems for traditional wire bonded or tape automated bonding (TAB) IC packages. Wire bonding and TAB packaging require that the die bond pads be disposed about the periphery of the semiconductor die.

The development of solder bump arrays has significantly increased the pinout capability of semiconductor dice by utilizing the surface area of the die itself to provide a field of bond sites. A key element of this pinout scheme is the use of a metal redistribution layer. This is an interconnect layer disposed atop a finished semiconductor die. Electrical connections from the interconnect layer are made to the underlying die bond pads which are typically disposed about the die periphery. The interconnects serve to redistribute the bond pads from the periphery over the surface area of the die, thus permitting higher I/O pinouts out of the die.

FIG. 1 is a cross-sectional view of a semiconductor device 100 in the prior art. The semiconductor device 100 of the prior art first provides a substrate 110 (e.g., die or wafer), which has an active surface 110a, on which a plurality of bonding pads 112 and a passivation layer 114 are disposed. The passivation layer 114 exposes the bonding pad 112. A first dielectric layer 116 is formed over the passivation layer 114. Then, patterning is performed on substrate 110 to form a redistribution layer (RDL) 118, which is disposed on the first dielectric layer 116 and electrically connected to bonding pad 112. Next, a second dielectric layer 120 is formed on substrate 110 to cover RDL 118. Afterwards, patterning is performed on the second dielectric layer 120 to form a plurality of openings, which exposes part of the RDL 118. Finally, a bumping process is performed to form the under bump metallization (UBM) pad 122 and bump 124 on the exposed RDL 118 of the opening.

As shown in FIG. 1, the bump 124 contacts the UBM pad 122 that connects to the RDL 118. The RDL 118 re-routes the bonding pad 112 to a location that is not directly under or aligned with the bump 124. The RDL 118 includes an offset via 118a and an RDL trace 118b that connects the bump 124 to bonding pad 112. The offset via 118a and RDL trace 118b increase RDL resistance and restrict the flexibility and routability of the bonding pad 112.

Traditionally, to solve this problem more offset vias were added, or the size of vias were increased. These solutions, however, lead to routing issues and increasing die size.

Accordingly, there is a need in the art for devices that improve chip performance by reducing RDL resistance and increasing flexibility.

### SUMMARY

To provide a semiconductor device with improved or reduced RDL resistance and increased flexibility in routing, a device is disclosed that includes bonding pads positioned under and aligned with an interconnection in the direction of the substrate. Since the pads are under the interconnection, vias coupling the pads to the interconnection are also under the interconnection, i.e., multiple “via under the interconnection structures.” The via under the interconnection structures provide less resistance to current flow through the RDL (due to a shorter RDL), increased flexibility in routing, and increased reliability of the semiconductor device.

The semiconductor device generally includes a plurality of bonding pads, a RDL formed over the bonding pads, a dielectric layer formed over the RDL, and an interconnection. The RDL is formed to include a plurality of vias for electrically coupling the bonding pads to the interconnection. The interconnection is attached to the semiconductor device through an opening in the dielectric layer. In various embodiments, the RDL is a copper RDL.

### BRIEF DESCRIPTION OF THE DRAWINGS

FIG. 1 is a cross-sectional view of a semiconductor device in accordance with the prior art.

FIG. 2 is a cross-sectional view of a semiconductor device in accordance with an embodiment of the present disclosure.

FIG. 3A is a plan view of an interconnection showing vias around the perimeter of the interconnection.

FIG. 3B is a plan view of an interconnection showing vias overlapping the interconnection.

FIG. 3C is a plan view of an interconnection showing vias under the center of the interconnection.

FIG. 4 is an integrated circuit package including a semiconductor device having via under the interconnection structures.

FIG. 5A is a cross-sectional view of a semiconductor device having bonding pads and a passivation layer.

FIG. 5B is a cross-sectional view of the semiconductor device from FIG. 6A after forming a first dielectric layer over the bonding pads and passivation layer.

FIG. 5C is a cross-sectional view of the semiconductor device from FIG. 6B after patterning the first dielectric layer.

FIG. 5D is a cross-sectional view of the semiconductor device from FIG. 6C after forming a RDL on the first dielectric layer.

FIG. 5E is a cross-sectional view of the semiconductor device from FIG. 6D after forming a second dielectric layer on the RDL.

FIG. 5F is a cross-sectional view of the semiconductor device from FIG. 6E after patterning the second dielectric layer.

FIG. 5G is a cross-sectional view of the semiconductor device from FIG. 6F after forming and attaching an interconnection.

FIG. 6 is a flowchart for a method of manufacture for a semiconductor device with via under the interconnection structures in accordance with an embodiment of the present disclosure.

FIG. 7 illustrates some example electronic systems incorporating a semiconductor device in accordance with an embodiment of the present disclosure.

Embodiments of the present disclosure and their advantages are best understood by referring to the detailed description that follows. It should be appreciated that like reference numerals are used to identify like elements illustrated in one or more of the figures.

### DETAILED DESCRIPTION

To meet the need in the art for semiconductor devices with reduced RDL resistance and increased flexibility in routing, a semiconductor device is provided that includes bonding pads positioned under and aligned with an interconnection in the direction of the substrate. Because the pads are located under the interconnection, vias coupling the pad to the interconnection are also under the interconnection, i.e., multiple “via under the interconnection structures.” In addition, since the bonding pads are under the interconnection, the length of the RDL, which is used to route signals between the pad and interconnection, is shorter, resulting in less resistance. In one embodiment, the RDL comprises copper. The semiconductor device generally includes a substrate with an active surface having a plurality of bonding pads, an RDL over the bonding pads, a dielectric layer over the RDL that includes an opening for receiving an interconnection, and an interconnection attached to the opening. In some embodiments, the semiconductor device comprises a wafer level package (WLP).

Overview

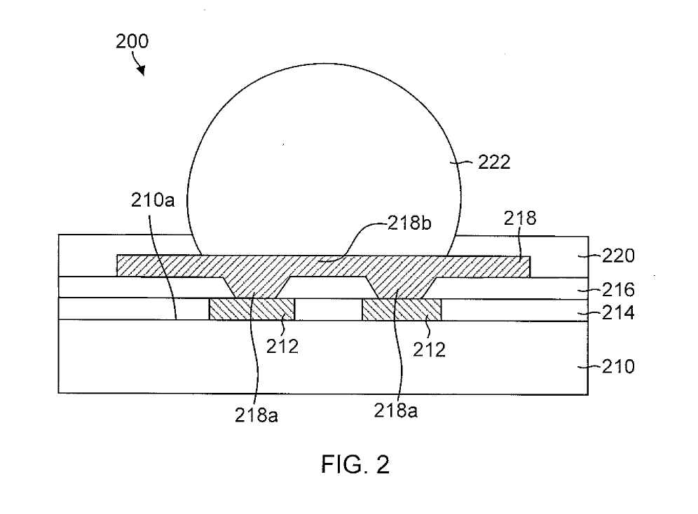

Turning now to the drawings, FIG. 2 shows an example semiconductor device 200 that includes a substrate 210 (e.g., die or wafer), which has an active surface 210a, on which a plurality of bonding pads 212 and a passivation layer 214 are disposed. The substrate 210 is formed from a semiconductor material, such as silicon, silicon germanium, quartz, or any other suitable material. The substrate 210 includes the necessary constituent substrate layer and its associated metal and insulative layers to fully define the circuitry for its intended functionality.

The semiconductor device 200 inputs/outputs an electrical signal from/to an external circuit through each of the plurality of bonding pads 212. The bonding pads 212 are made with a conductive material, such as aluminum, copper, tin, nickel, gold, or silver, and are electrically connected to the circuit elements formed within the substrate 210. The bonding pads 212 may be formed by physical vapor deposition (PVD), chemical vapor deposition (CVD), electrolytic plating, or an electroless plating process.

The passivation layer 214 is formed on peripheral areas of the bonding pads 212 and the active surface 210a of the substrate 210, while exposing the bonding pads 212 through openings. The passivation layer 214 protects the substrate 210 from external impacts and is made of an insulating material. For example, the material used to form the passivation layer 214 may be silicon dioxide, silicon nitride, silicon oxynitride, or a combination thereof.

A first dielectric layer 216 is formed over the passivation layer 214 and patterned to include openings that expose central portions of the bonding pads 212. The first dielectric layer 216 may be formed, for example, from polyimide.

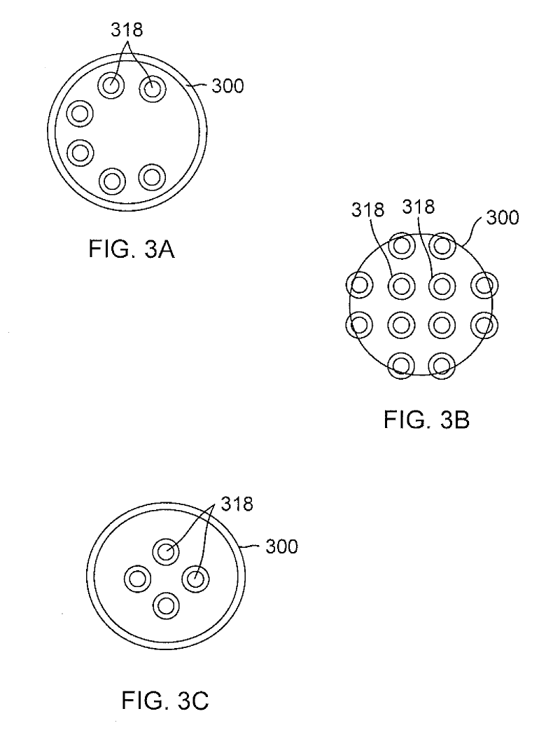

A RDL 218 is formed over the first dielectric layer 216. The RDL 218 includes an RDL trace 218b and vias 218a, and establishes an electric route connecting the bonding pads 212 to the interconnection (e.g., solder bump) 222. In one embodiment, the vias 218a may be located directly underneath a portion of the RDL trace 218b. In another embodiment, the vias 218a may be located underneath the interconnection 222. In another embodiment, the vias 218a may be located directly underneath a portion of the RDL trace 218b while the vias 218a are located over the bonding pad 212. In another embodiment, the vias 218a and the bonding pad 212 are located underneath the interconnection 222. FIG. 2 shows two vias 218a, however the disclosure is not so limited (see later discussion regarding FIG. 3). In one embodiment, the vias 218a are a means for electrically connecting bonding pads 112 to the interconnection 222 with reduced RDL resistance. The RDL 218 can be made with nickel, copper, or other conductive materials, and may be formed by PVD, CVD, electrolytic plating, or electroless plating process. In one embodiment, the RDL 218 includes copper.

A second dielectric layer 220, which may also be polyimide or other photoimageable polymer like benzocyclobutene (BCB) or polybenzoxazole (PBO), is formed on substrate 210 to cover the RDL 218. The second dielectric layer 220 is patterned to form a plurality of openings, which expose a part of the RDL 218. The second dielectric layer 220 protects the RDL 218 and substrate 210, and is provided for electrically insulating the RDL 218 and substrate 210.

The interconnection 222 (e.g., solder bump, copper pillar, or other interconnect) is formed on the exposed RDL 218 of the opening and can be coupled to an external circuit to input/output an electrical signal. The semiconductor device 200 may be coupled to motherboards, printed circuit boards (PCB) or other substrates using interconnection 222 as an interconnect structure for placing the substrate 210 in communication with other system components. The interconnection 222 may be made of a general solder material. Solder material can be any metal or electrically conductive material, such as tin, lead, gold, silver, copper, zinc, bismuth, and alloys thereof.

As shown, semiconductor device 200 eliminates the UBM pad so that there may be direct contact between the interconnection 222 and the RDL 218. In other embodiments, a UBM pad may be present between the interconnection 222 and the RDL 218. In various implementations, the UBM pad provides improved reliability to the chip.

In contrast to traditional implementations, at least one of the bonding pads 212 is under and aligned with the interconnection 222. By “under” the interconnection is meant the side of the interconnection proximate the active surface 210a of the substrate 210.

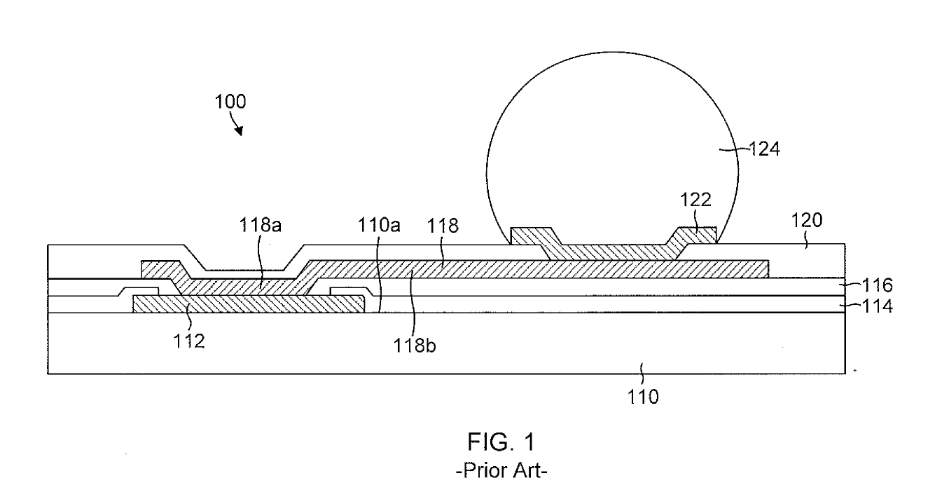

Because the bonding pad 212 is under and aligned with the interconnection, offset vias, such as those shown in FIG. 1 (see 118a) are no longer required. Since the bonding pad 212 is under the interconnection 222, the via 218a coupling the bonding pad 212 to the interconnection 222 is also under the interconnection 222. By placing the vias under the interconnection 222, the length of the RDL 218 is made shorter. For example, the length of the RDL 218 is from about 150-300 μm. This is about a 30% reduction in the length of a traditional RDL. The use of a shorter RDL results in less resistance to current flow through the RDL 218 because of the shorter path length. The shorter path length also results in good thermal conductivity of the RDL 218.

Increased flexibility in routing is another advantage of the present disclosure. Via placement is flexible, and multiple vias may be placed under the interconnection in different configurations without using extra routing space. Increasing the number of vias also decreases the resistance to current flow through RDL 218. FIGS. 3A, 3B and 3C show top views or plan views of an interconnection with vias around the perimeter of the interconnection. FIG. 3A illustrates the vias 318 placed under and around the perimeter of the interconnection 300. FIG. 3B shows the vias 318 under and overlapping the interconnection 300. In FIG. 3C, the vias 318 are under the center of the interconnection 300.

In addition, the semiconductor devices including these vias have increased reliability. In an exemplary embodiment, the resulting device improves Board Level Reliability (BLR) performance, and can improve electromigration performance (e.g., less resistance so less heating).

Wafer Level Package Embodiment

WLP refers to semiconductor packages that are formed at the wafer level prior to singulation and then singulated into their individual dies. As a result, WLPs can have a small foot print size—often as small as the fabricated die itself. WLPs can be formed on the same wafer as an active die or active dies can be attached to a wafer substrate. WLPs can streamline the semiconductor manufacturing process by fully integrating wafer fabrication, packaging and even testing.

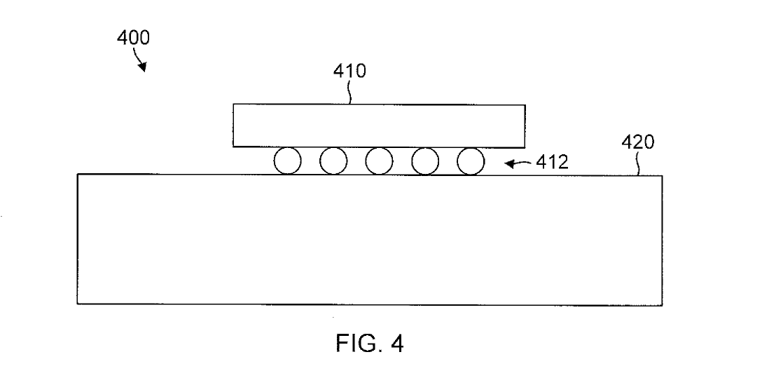

FIG. 4 illustrates a flip-chip package 400 in accordance with one or more embodiments. Package 400 includes a semiconductor device in the form of a WLP 410 that electrically (and mechanically) couples with a PCB 420 by means of solder bumps 412 as known in the flip-chip packaging arts. Alternatively humps 412 may be replaced by copper pillars or other suitable interconnects.

The WLP 410 includes a die (not shown) with integrated circuits that are fabricated using techniques known in the art such as etching, lithography, deposition, doping, etc. The circuits may include one or more transistors, diodes, inductors, capacitors, resistors, and other circuit elements formed within the active region of the die. Bonding pads made of a conductive material are electrically connected to the circuit elements formed within the die. Bumps 412 are electrically connected to the bonding pads to route electrical signals to/from the PCB 420.

Example Methods of Manufacture

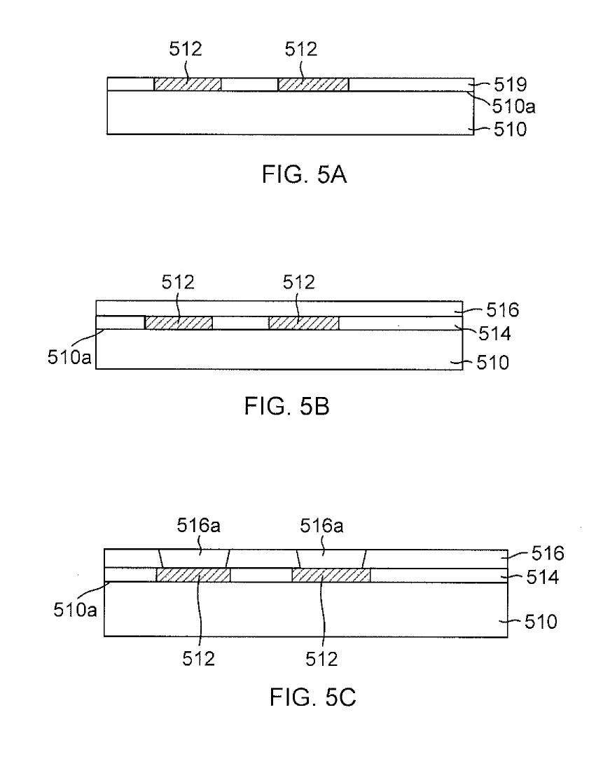

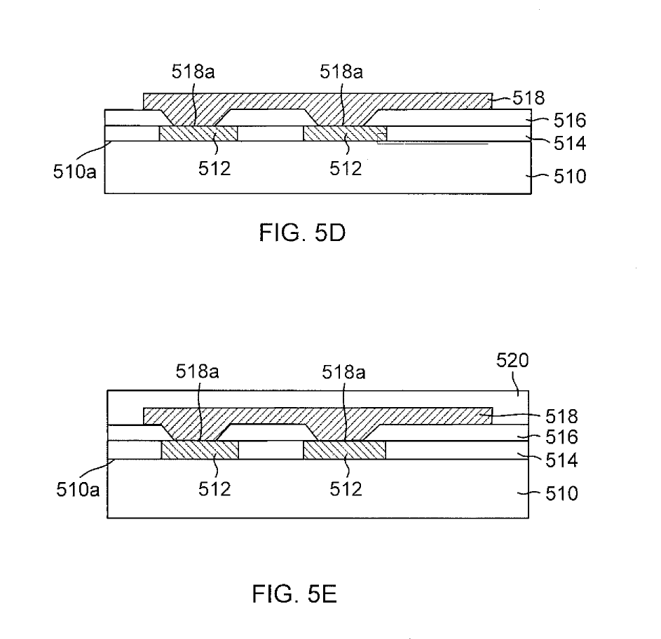

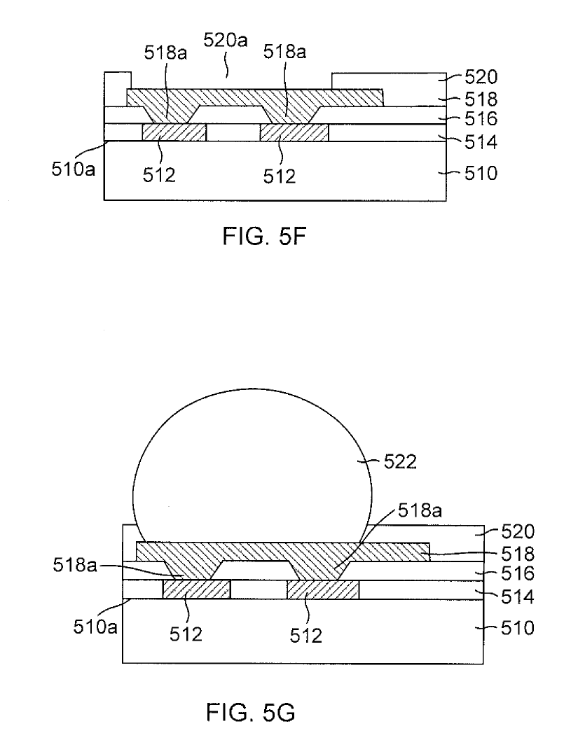

FIG. 5A through FIG. 5G illustrate manufacturing steps for forming a semiconductor device with via under the interconnection structures, such as the semiconductor device of FIG. 2.

First, as shown in FIG. 5A, a substrate 510 is provided. To simplify the figure, this embodiment only illustrates the cross-sectional view of part of the substrate 510. The substrate 510 has an active surface 510a, on which a plurality of bonding pads 512 are disposed, and a passivation layer 514 that exposes the bonding pads 512.

In FIG. 5B, a first dielectric layer 516 is formed over bonding pads 512 and passivation layer 514. In FIG. 5C, the first dielectric layer 516 is patterned to form openings 516a to expose bonding pads 12.

FIG. 5D illustrates a metal layer formed on the first dielectric layer 516 to couple with the bonding pads 512. The metal layer is patterned to form a RDL 518. The RDL 518 is formed over first dielectric layer 16 and fills openings 516a to form vias 518a to the underlying bonding pads 512. The RDL 518 can be patterned by depositing and lithographically patterning a photoresist layer over the RDL 518. The RDL 518 is then etched.

Referring now to FIG. 5E, a second dielectric layer 520 is formed on substrate 510 to cover RDL 518. In FIG. 5F, patterning is executed on the second dielectric layer 520 to form a plurality of openings 520a (only one is illustrated) for bump sites, which exposes part of the RDL 518. When the second dielectric layer 520 is made of photographic material, patterning second dielectric layer 520 may adopt steps of exposure and developing. On the other hand, if the second dielectric layer 520 is not made of photographic material, photoresistant material (liquid photoresist or dry film) may be applied as mask for the patterning, so as to facilitate the procedure of etching on second dielectric layer 520.

Then, as shown in FIG. 5G, interconnection (e.g., bump) 522 is attached to parts of RDL 518 exposed by opening 520a. In other embodiments, a UBM pad may be present. The interconnection 522 can include tin-lead alloy, gold or conductive polymer. In various embodiments, solder material is deposited and reflowed into the opening 520a to physically and electrically couple the interconnection 522 to RDL 518.

Method of Manufacturing Flowchart

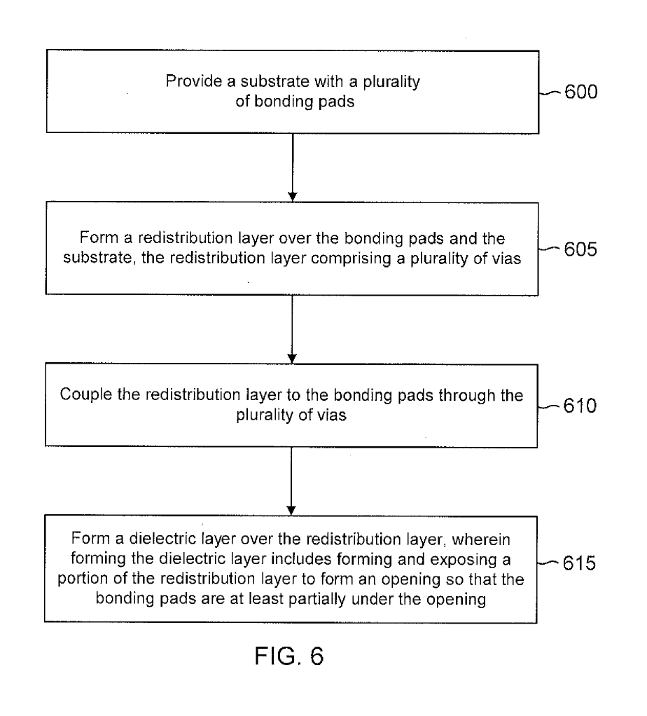

A manufacturing process generic to the various embodiments discussed herein may be summarized as shown in a flowchart of FIG. 6. A first step 600 comprises providing a substrate with a plurality of bonding pads. This step is illustrated, for example, in FIG. 5A. A second step 605 comprises forming a RDL over the bonding pads and the substrate. The RDL includes a plurality of vias. An example of this step is shown in FIG. 5D. A third step 610 comprises coupling the RDL to the bonding pads through a plurality of vias. This step is illustrated, for example, in FIG. 5D. Finally, the process includes a step 615 of forming a dielectric layer over the RDL, wherein forming the dielectric layer includes forming and exposing a portion of the RDL to form an opening so that the bonding pads are at least partially under the opening. In various embodiments, the opening is configured to receive an interconnection, and the bonding pads are located under the interconnection. This step is illustrated, for example, in FIGS. 5E-5F. Because the bonding pads are under the interconnection, the vias coupling the bonding pads to the interconnection are also under the interconnection. This placement of the vias provide less resistance to current flow through the RDL, increased flexibility in routing, and increased reliability of the semiconductor device.

Example Electronic Systems

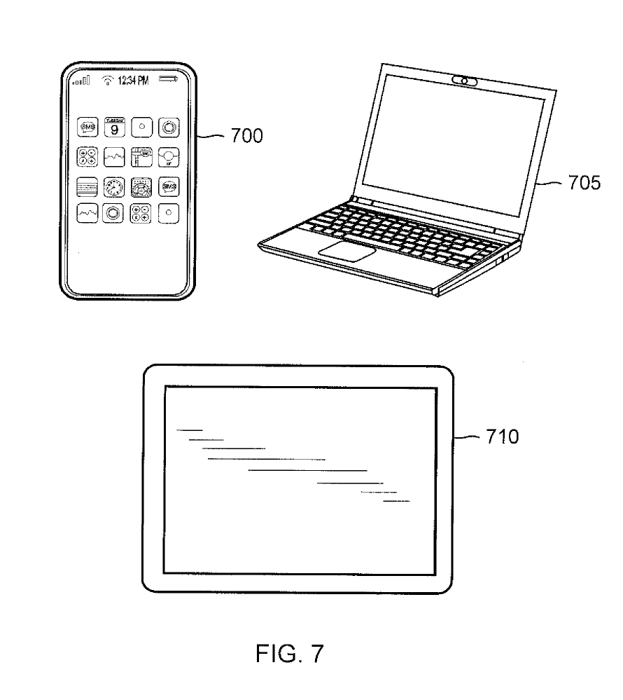

Integrated circuit packages including a semiconductor device as disclosed herein may be incorporated into a wide variety of electronic systems. For example, as shown in FIG. 7, a cell phone 700, a laptop 705, and a tablet PC 710 may all include an integrated circuit package incorporating a semiconductor device constructed in accordance with the disclosure. Other exemplary electronic systems such as a music player, a video player, a communication device, and a personal computer may also be configured with integrated circuit packages constructed in accordance with the disclosure.

As those of some skill in this art will by now appreciate and depending on the particular application at hand, many modifications, substitutions and variations can be made in and to the materials, apparatus, configurations and methods of use of the devices of the present disclosure without departing from the spirit and scope thereof. In light of this, the scope of the present disclosure should not be limited to that of the particular embodiments illustrated and described herein, as they are merely by way of some examples thereof but rather, should be fully commensurate with that of the claims appended hereafter and their functional equivalents.

1. A semiconductor device, comprising:
a plurality of bonding pads on a substrate;
a redistribution layer trace coupled to each of the plurality of bonding pads through a plurality of vias;
a dielectric layer over the redistribution layer trace, the dielectric layer including an opening that exposes a portion of the redistribution layer trace, wherein each of the plurality of bonding pads is at least partially under the opening.

2. The semiconductor device of claim 1, wherein the opening is configured to receive an interconnection.

3. The semiconductor device of claim 1, wherein the redistribution layer trace has a reduced length of 150 to 300 μm, and the length is measured in a plane of an active side of the substrate.

4. The semiconductor device of claim 1, wherein an interconnection is directly coupled to the redistribution layer trace.

5. The semiconductor device of claim 1, wherein the plurality of vias are at least partially under the opening.

6. The semiconductor device of claim 1, wherein the redistribution layer trace comprises copper.

7. The semiconductor device of claim 1, further comprising an under bump metallization pad formed between the dielectric layer and the interconnection an electrically connecting the interconnection with the redistribution layer trace.

8. The semiconductor device of claim 1, wherein the bonding pads are under and around a periphery of the opening.

9. The semiconductor device of claim 1, wherein the semiconductor device comprises a wafer level package substrate.

10. The wafer level package substrate of claim 9, the wafer level package substrate incorporated into at least one of a cellphone, a laptop, a tablet, a music player, a communication device, a computer, and a video player.

11. A method comprising:
providing a substrate with a plurality of bonding pads;
forming a redistribution layer trace over the bonding pads and the substrate, the redistribution layer trace comprising a plurality of vias;
coupling the redistribution layer trace to each of the plurality of bonding pads through the plurality of vias; and
forming a dielectric layer over the redistribution layer trace, wherein forming the dielectric layer includes forming and exposing a portion of the redistribution layer trace to form an opening so that each of the plurality of bonding pads are at least partially under the opening.

12. The method of claim 11, further comprising electrically coupling the substrate to an external circuit through an interconnection received in the opening.

13. The method of claim 12, wherein the interconnection is coupled directly to the redistribution layer trace.

14. The method of claim 11, wherein electrically coupling the substrate to an external circuit through an interconnection comprises depositing solder material on the opening and reflowing the solder material.

15. The method of claim 11, wherein forming the redistribution layer trace comprises forming a redistribution layer trace having a reduced length of 150 to 300 μm.

16. The method of claim 11, wherein the plurality of vias are at least partially under the opening.

17. The method of claim 11, wherein the redistribution layer trace comprises copper.

18. A device, comprising:
a substrate with a plurality of bonding pads;
a redistribution layer trace coupled to each of the plurality of bonding pads through vias; and
a dielectric layer over the redistribution layer trace including an opening that exposes a portion of the redistribution layer trace, wherein each of the plurality of bonding pads is at least partially under the opening.

19. The device of claim 18, further including an interconnection in the opening and directly coupled to the redistribution layer trace.

20. The device of claim 18, wherein the redistribution layer trace is coupled to each of the plurality of bonding pads through a plurality of vias, the plurality of vias being at least partially under the opening.

21. The method of claim 11, further comprising an under bump metallization pad coupling the redistribution layer trace and the interconnection.
